(19) United States
(12) Patent Application Publication
(10) Pub. No.: US 2006/0093004 A1
(43) Pub. Date: May 4, 2006

(54) Semiconductor laser device and method for manufacturing the same

(75) Inventor: Byung Jin Ma, Suwon (KR)

Correspondence Address: McDermott Will & Emery LLP, 600 13th Street, N.W., Washington, DC, 20005-3096, US

(73) Assignee: SAMSUNG ELECTRO-MECHANICS CO., LTD.

(21) Appl. No.: 11/159,151

(22) Filed: Jun. 23, 2005

(30) Foreign Application Priority Data
Oct. 29, 2004 (KR) 10-2004-87203

(51) Int. Cl. H01S 5/00; H01L 21/00

(52) U.S. Cl. 372/46.01; 438/22

(57) ABSTRACT

Provided are a semiconductor laser device and a method for manufacturing the same. The method comprises the steps of: sequentially laminating a first conductivity-type clad layer, an active layer, a second conductivity-type clad layer, and a second conductivity-type cap layer on a substrate; forming a metal film pattern on the second conductivity-type cap layer; forming a protective insulating film pattern on the metal film pattern; etching the second conductivity-type cap layer and the second conductivity-type clad layer using the protective insulating film pattern as an etching mask to form a ridge structure on the second conductivity-type clad layer; forming a current blocking layer over a whole surface of the laminate; exposing the metal film pattern to form a contact opening; and forming a top electrode layer on a surface of the metal film pattern exposed by the contact opening.

### RELATED APPLICATIONS

The present application is based on, and claims priority from, Korean Application Number 2004-87203, filed Oct. 29, 2004, the disclosure of which is incorporated by reference herein in its entirety.

### BACKGROUND OF THE INVENTION

1. Field of the Invention

The present invention relates to a semiconductor laser device, and a method for manufacturing the device. More specifically, the present invention relates to a ridge-type semiconductor laser device having improved laser output characteristics due to the reduced contact resistance with a top electrode, and a method for manufacturing the device.

2. Description of the Related Art

In recent years, semiconductor laser devices have been applied to a wide range of fields, including optical sensors, optical communications, optical pick-ups, displays, and medical instruments. The semiconductor laser devices for use in these applications are particularly required to have a high output. An AlGaAs or AlGaInP-based semiconductor laser device is currently used as a light source for compact disc (CD) and digital video disc (DVD) systems. Particularly, a next generation optical storage system which uses a bluish-purple semiconductor laser device capable of emitting light at a wavelength of 405 nm as a light source has been developed, and is now being manufactured on a commercial scale. In order to allow the optical storage system to store a large amount of information at a high speed, it is necessary to develop a high-output semiconductor laser device capable of providing a sufficient optical output within the range of several tens of milliwatts to several hundreds of milliwatts (mW). Further, to operate a high-output semiconductor laser device at high performance, an ohmic contact resistance with an electrode should be minimized such that current injection is facilitated.

A general semiconductor laser device comprises upper and lower clad layers for current injection, and an active layer disposed between the clad layers in which induced emission of photons substantially occurs. The upper clad layer (e.g., p-type clad layer) of the general semiconductor laser device is formed in a ridge structure so that current is injected through the ridge only, thereby achieving improved current injection efficiency. That is, the ridge serves as a waveguide of the semiconductor laser device. PCT Publication WO 2000/04615 discloses a ridge-type nitride-based group III compound semiconductor laser device, and a method for manufacturing the semiconductor laser device.

FIGS. 1a to 1d are cross-sectional views illustrating a conventional method for manufacturing a ridge-type semiconductor laser device. Referring to FIG. 1a, an n-type clad layer 12, an active layer 13, a p-type clad layer 14, and a p-type cap layer 15 are sequentially laminated on a GaAs substrate, and then a photoresist or an insulating film 16 made of SiO₂ or SiN is formed on the laminate. Thereafter, as shown in FIG. 1b, an insulating mask pattern 16a is formed to form a ridge structure. Next, the p-type cap layer is etched using the mask pattern 16a as an etching mask to form a ridge, as shown in FIG. 1c. Thereafter, as shown in FIG. 1d, the mask pattern 16a is removed, and a current blocking layer 17 composed of an insulating layer, e.g., SiO₂, is formed. Next, the current blocking layer 17 is patterned by selective etching to expose a portion of the upper surface of the ridge (i.e. a contact opening 20) only through which a current is injected (see, FIG. 1e). Current injection for light output is achieved from the upper surface of the ridge opened by the contact opening 20. Finally, as shown in FIG. 1f, a metal is deposited on the resulting laminate to form a top electrode structure.

However, the conventional method and the semiconductor laser device manufactured by the method have the following problems.

First, the width of the region opened by the current blocking layer 17 (i.e. width of the contact opening 20) should be smaller than that of the ridge in order to ensure a sufficient process margin. Specifically, since the width of the ridge is as small as a few micrometers, there arises a danger of misalignment when the contact opening 20 is formed by selective etching. In order to prevent this danger, the upper surface of the ridge should be opened to a width smaller than the width of the ridge such that a sufficient process margin is ensured (see, FIG. 1e). Accordingly, the contact area between the metal layer 18 and the semiconductor through the opened region becomes small. This small contact area increases an ohmic contact resistance value affecting the output characteristics of the semiconductor laser device.

Secondly, there is a danger that the surface of the semiconductor layer affecting the ohmic contact resistance characteristics may be damaged upon selective etching of the current blocking layer 17 for formation of the contact opening 20. As processes for forming the contact opening 20 by selectively etching the current blocking layer 17, wet etching and dry etching processes are taken into consideration. The wet etching process has the advantage that since the etching selection ratio of the insulating layer (i.e. current blocking layer 17) to the semiconductor (i.e. p-type cap layer 15) is high, the current blocking layer can be selectively etched without damage to the semiconductor surface. However, since the wet etching process has low accuracy of pattern transcription, compared to the dry etching process, undercuts may be formed beneath the ends of the etching mask. For these reasons, the wet etching process is unsuitable for the formation of the contact opening 20 requiring a very small critical dimension (CD). In contrast to the wet etching process, the dry etching process is commonly used to form the contact opening 20. However, the use of the dry etching process causes damage to the upper surface of the p-type cap layer 15 due to an insufficient etching selection ratio between the semiconductor and the insulating layer. Damage to the surface of the p-type cap layer 15 acts as a cause of increased ohmic contact resistance.

The problems encountered with both processes undesirably increase the ohmic contact resistance between the top electrode and the underlying semiconductor, causing an increase in operation voltage and current. As a result, the high-temperature and high-output characteristics of the semiconductor laser device are deteriorated, and the performance of the semiconductor laser device is degraded.

### SUMMARY OF THE INVENTION

Therefore, the present invention has been made in view of the above problems, and it is an object of the present invention to provide a method for manufacturing a semiconductor laser device wherein the ohmic contact resistance between a top electrode and an underlying semiconductor layer is reduced, thereby improving high-temperature and high-output operational characteristics of the semiconductor laser device.

It is another object of the present invention to provide a semiconductor laser device having reduced ohmic contact resistance between a top electrode and an underlying semiconductor layer.

In accordance with a first embodiment of a first aspect of the present invention, there is provided a method for manufacturing a semiconductor laser device, comprising the steps of: sequentially laminating a first conductivity-type clad layer, an active layer, a second conductivity-type clad layer, and a second conductivity-type cap layer on a substrate; forming a metal film pattern for formation of a ridge structure on the second conductivity-type cap layer; etching the second conductivity-type cap layer and the second conductivity-type clad layer using the metal film pattern as an etching mask to form a ridge structure on the second conductivity-type clad layer; forming a current blocking layer over a whole surface of the laminate on which the ridge structure is formed; selectively etching the current blocking layer by photolithography to expose the metal film pattern and to form a contact opening; and forming a top electrode layer on a surface of the metal film pattern exposed through the contact opening and on the current blocking layer.

In the method of the first embodiment, it is preferred that the step of forming a ridge structure is performed by wet etching. In the step of forming a contact opening, the contact opening is preferably formed to a width smaller than the width of the ridge in order to prevent the problem of misalignment. The step of forming a metal film pattern can be performed by a lift-off process.

In accordance with a second embodiment of a first aspect of the present invention, there is provided a method for manufacturing a semiconductor laser device, comprising the steps of: sequentially laminating a first conductivity-type clad layer, an active layer, a second conductivity-type clad layer, and a second conductivity-type cap layer on a substrate; forming a metal film pattern on the second conductivity-type cap layer; forming a protective insulating film pattern on the metal film pattern to protect the metal film pattern; etching the second conductivity-type cap layer and the second conductivity-type clad layer using the protective insulating film pattern as an etching mask to form a ridge structure on the second conductivity-type clad layer; forming a current blocking layer over a whole surface of the laminate on which the ridge structure is formed; selectively etching the current blocking layer to expose the metal film pattern and to form a contact opening; and forming a top electrode layer on a surface of the metal film pattern exposed by the contact opening and on the current blocking layer.

In the method of the second embodiment, the step of forming a protective insulating film pattern may include the sub-steps of forming an insulating film on the metal film pattern, and selectively etching the insulating film to remove all portions except for a portion of the insulating film surrounding the metal film pattern. The protective insulating film pattern can be formed of SiO₂, Si₃N₄, SiON, or the like.

Preferably, the step of forming a ridge structure is performed by dry etching. Preferably, the method of the second embodiment may further comprise the step of removing the protective insulating film after the step of forming a ridge structure and prior to the step of forming a current blocking layer. In the step of forming a contact opening, the contact opening is preferably formed to a width smaller than the width of the ridge in order to prevent the problem of misalignment.

In accordance with a second aspect of the present invention, there is provided a semiconductor laser device, comprising: a first conductivity-type clad layer and an active layer sequentially laminated on a substrate; a second conductivity-type clad layer formed on the active layer, the second conductivity-type clad layer having an upper region in a ridge structure; a second conductivity-type cap layer formed on an upper surface of the ridge structure of the second conductivity-type clad layer; a metal film pattern formed on the second conductivity-type cap layer; a current blocking layer formed on a portion of an upper surface of the metal film pattern, both sides of the second conductivity-type cap layer, both sides of the ridge structure, and a bottom side of the second conductivity-type clad layer around the ridge structure, thereby exposing a portion of an upper surface of the metal film pattern; and a top electrode layer formed on a portion of the exposed upper surface of the metal film pattern and on the current blocking layer.

In one embodiment of the second aspect of the present invention, the width of the metal film pattern may be smaller than that of the ridge. In another embodiment, the width of the metal film pattern may be substantially identical to that of the ridge. In addition, the semiconductor laser device of the present invention can be composed of an AlGaInP, AlGaAs, InGaAsP, AlInGaAs, or InGaN based semiconductor compound.

The present invention provides a solution to reduce the ohmic contact resistance between a top electrode and a semiconductor layer in a ridge-type semiconductor laser device. To this end, a metal film pattern (or a protective insulating film pattern formed on the metal film pattern) formed on the semiconductor layer is etched using an etching mask to form a ridge structure. According to the semiconductor laser device of the present invention, the contact area between the metal and the semiconductor is large, and additionally damage to the semiconductor surface affecting the ohmic contact resistance can be prevented.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1f are cross-sectional views illustrating a conventional method for manufacturing a semiconductor laser device;

FIGS. 2 to 7 are cross-sectional views illustrating a method for manufacturing a semiconductor laser device according to one embodiment of the present invention; and

FIGS. 8 to 13 are cross-sectional views illustrating a method for manufacturing a semiconductor laser device according to another embodiment of the present invention.

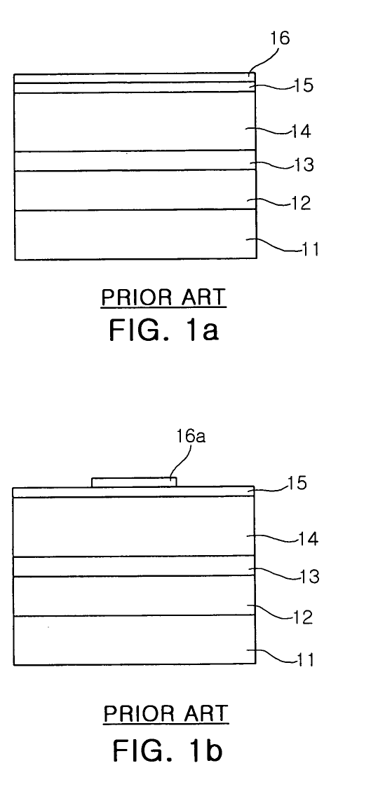

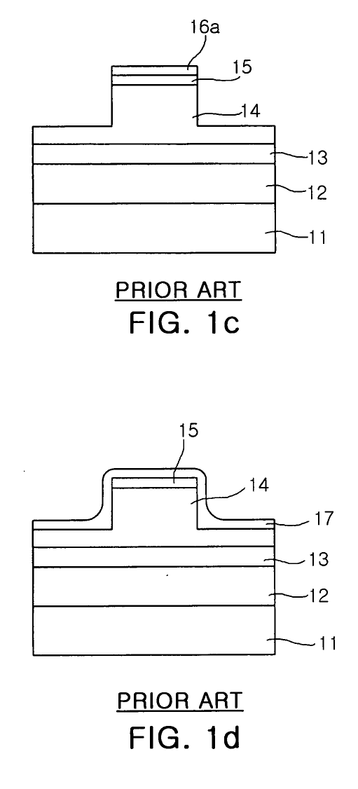

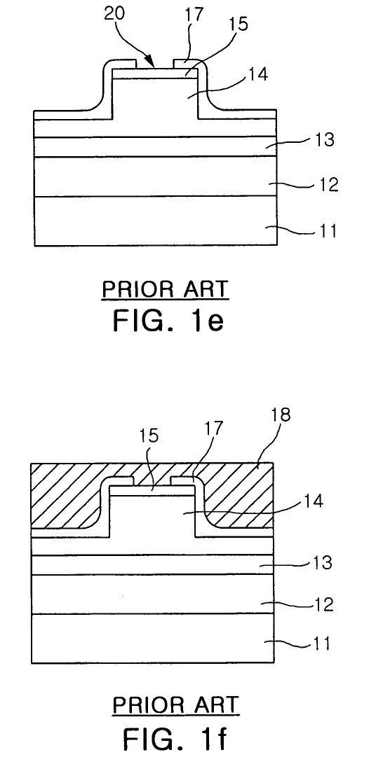

### DESCRIPTION OF THE PREFERRED EMBODIMENTS

Detailed description will be made of embodiments of the present invention with reference to the accompanying drawings. However, various modifications to the embodiments of the present invention may easily be made, and the scope of the present invention is not limited by the following embodiments. These embodiments are provided to those skilled in the art for a better understanding of the present invention. In the drawings, the shape and size of elements may be exaggerated for the purpose of clarity, and the same elements are denoted by the same reference numerals even though they are depicted in different drawings.

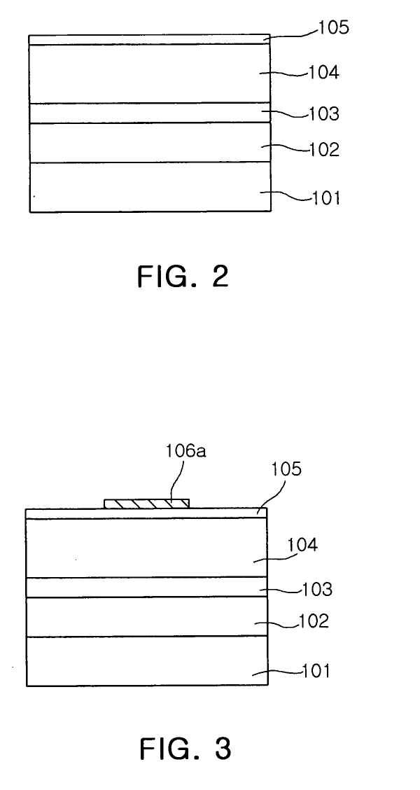

FIGS. 2 to 7 are cross-sectional views illustrating a method for manufacturing a semiconductor laser device according to one embodiment of the present invention. In the present embodiment, a metal film pattern is etched using an etching mask to form a ridge structure. At this time, since the etching mask is made of metal, wet etching is preferably used to form the ridge structure.

Referring to FIG. 2, an n-type clad layer 102, an active layer 103, a p-type clad layer 104, and a p-type cap layer 105, all of which are composed of an AlGaInP or GaInP semiconductor, are sequentially formed on a GaAs substrate 101, such as a semiconductor substrate. At this step, the formation of the p-type cap layer 105 is intended for a reduction in band discontinuity and an ohmic contact with a top electrode.

As shown in FIG. 3, a metal film pattern 106a for formation of a ridge structure is formed on the p-type cap layer 105. The metal film pattern 106a can be formed, for example, by a lift-off process. Specifically, a photoresist film is applied to the p-type cap layer 105, and is then patterned to form an opening in a region where the p-type cap layer 105 is exposed and thus the metal film pattern 106a is to be formed. At this step, exposure time, baking conditions, and the like are controlled in such a manner that the opening of the photoresist has a bottom portion wider than an upper portion. Thereafter, a metal film, for example, including Ti/Pt or Ti/Mo, is formed to a thickness smaller than that of the photoresist film on the photoresist film and the exposed p-type cap layer 105, and then the photoresist film is removed using a stripper. Upon stripping, the photoresist film is removed to leave the metal film pattern 106a on the p-type cap layer 105, as shown in FIG. 3. In the case of a semiconductor laser device having a wavelength of 650 nm, the width of the metal film pattern 106a may be about 1 μm to about 2 μm.

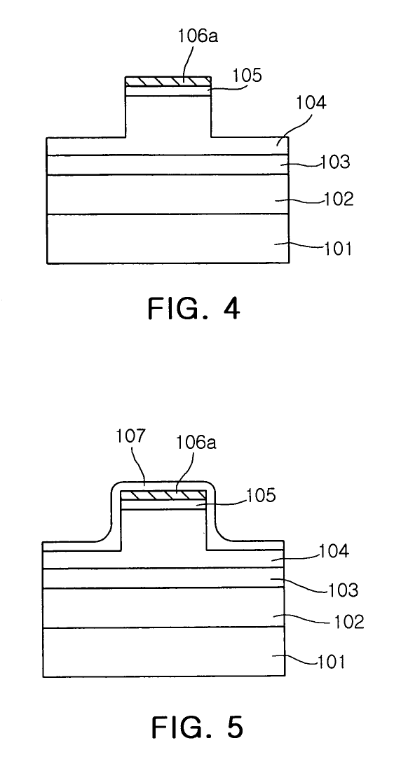

As shown in FIG. 4, the p-type cap layer 105 and the p-type clad layer 104 are etched using the metal film pattern 106a as an etching mask to form a ridge structure. At this step, the p-type clad layer 104 is etched to a predetermined depth, allowing portions of the p-type clad layer 104 to remain at both sides of the ridge structure. In the present embodiment, it is preferred to form the ridge structure by wet etching. The metal film pattern 106a can be easily sputtered during dry etching.

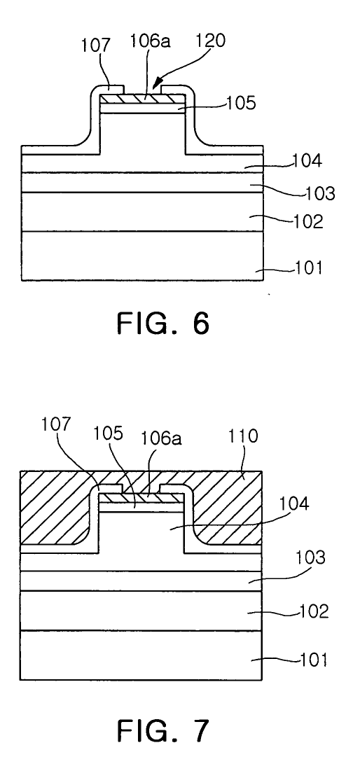

Subsequently, a current blocking layer 107 as an insulating layer is formed over the whole surface of the resulting structure, as shown in FIG. 5. The current blocking layer 107 as an insulating layer can be formed of SiO₂, SiN, or the like. As shown in FIG. 6, the current blocking layer 107 is selectively dry-etched or wet-etched in such a way that a portion of the upper surface of the metal film pattern 106a is exposed to form a contact opening 120. At this step, the width of the contact opening 120 may be sufficiently smaller than that of the ridge structure. Next, a top electrode layer 110 is formed over the whole surface of the resulting structure to manufacture the final semiconductor laser device shown in FIG. 7.

According to the present embodiment, a semiconductor-metal interface for an ohmic contact is formed between the metal film pattern 106a and the p-type cap layer 105. Accordingly, the width of the ohmic contact face is almost the same as that of the ridge structure. Further, since the ridge structure is formed after the formation of the metal film pattern 106, no damage to the upper surface of the p-type cap layer 105 by etching occurs. In conclusion, due to an increase in the contact area at the ohmic contact face and no damage to the semiconductor surface, the ohmic contact resistance is reduced when compared to prior art laser devices. Further, although the width of the contact opening 120 is sufficiently small, there is no influence on the ohmic contact resistance. Accordingly, since the contact opening 120 can be formed to have a small width without the need of increasing the ohmic contact resistance, a process margin in alignment is improved, thus greatly contributing to an improvement in the process yield of the semiconductor laser device.

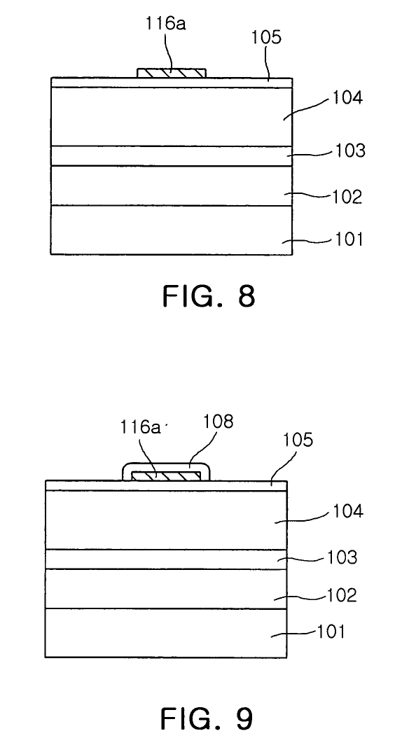

FIGS. 8 to 13 are cross-sectional views illustrating a method for manufacturing a semiconductor laser device according to another embodiment of the present invention. As explained earlier in FIG. 2, an n-type clad layer 102, an active layer 103, a p-type clad layer 104, and a p-type cap layer 105 are sequentially formed on a substrate 101. Subsequently, a metal film pattern 116a is formed on the p-type cap layer 105, as shown in FIG. 8. As described above, the metal film pattern 116a can be formed by a lift-off process.

Next, as shown in FIG. 9, an insulating layer made of SiO₂, Si₃N₄, SiON, or the like is formed on the metal pattern 116a, and is then patterned to form a protective insulating film pattern surrounding the metal film pattern 108. The protective insulating film pattern 108 functions as an etching mask upon dry etching for formation of a ridge structure in the subsequent step. The protective insulating film pattern 108 can be made of, for example, SiO₂, Si₃N₄, SiON, or the like. If dry etching, e.g., reactive ion etching (RIE) or inductively coupled plasma (ICP) etching, is performed in a state where the metal film pattern 106a is exposed, the metal film pattern 106a may be sputtered. Accordingly, the protective insulating film pattern 108 serves to protect the metal film pattern 116a in the present embodiment.

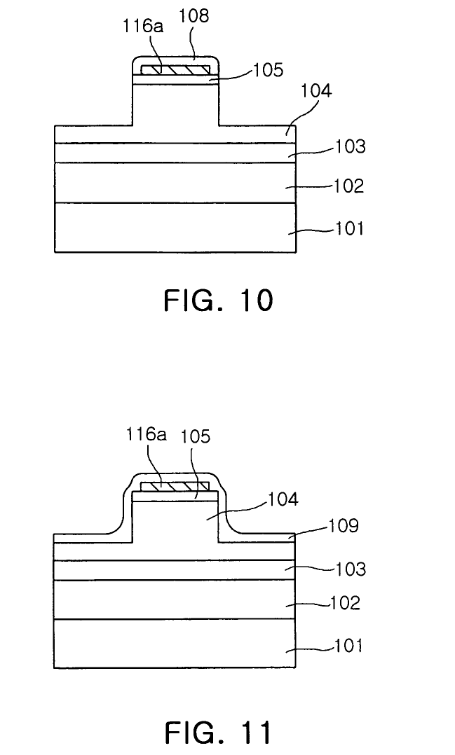

Next, the p-type cap layer 105 and the p-type clad layer 104 are etched using the protective insulating film pattern 108 as an etching mask to form a ridge structure on the p-type clad layer 104, as shown in FIG. 10. Since an anisotropic dry etching process is employed in the present embodiment, unlike in the previous embodiment, the width and shape of the ridge structure can be more accurately controlled. In addition, since dry etching is performed using the protective insulating film pattern 108 as an etching mask, instead of the exposed metal film pattern (see, 106a shown in FIG. 4), no sputtering of the metal film pattern 116a occurs, ensuring process stability of the etching.

If dry etching is performed in a state where the metal film pattern 116a is exposed, the metal film pattern 116a is sputtered by plasma ions, etc., causing damage to the metal film pattern 116a. In addition, metal materials sputtered from the metal film pattern 116a are scattered and are deposited. The deposited metal materials act as masks interfering with the etching, and as a result, contaminate a reaction chamber or the device to be manufactured. The protective insulating film pattern 108 plays a role in protecting the metal film pattern 116a from the problems associated with sputtering.

Next, as shown in FIG. 11, after the protective insulating film pattern 108 is removed, a current blocking layer 109 as an insulating layer made of SiO₂ or SiN is formed over the whole surface of the resulting structure. Alternatively, the current blocking layer 109 may be directly formed on the resulting structure without removal of the protective insulating film pattern 108. However, for improved accuracy of the subsequent etching process, it is desirable that the difference in the height between the ridge portion and portions around the ridge portion is as small as possible. Accordingly, it is more preferred that the current blocking layer 109 is formed after removal of the protective insulating film pattern 108.

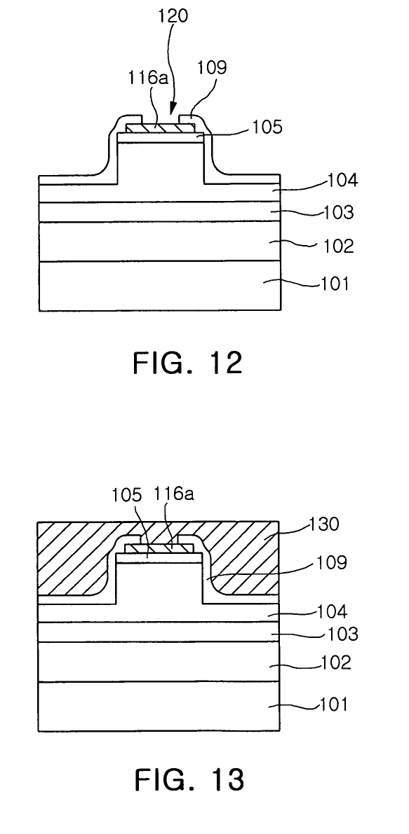

Thereafter, as shown in FIG. 12, the current blocking layer 109 is selectively dry-etched in such a manner that a portion of the upper surface of the metal film pattern 116a is exposed to form a contact opening 120. At this step, the width of the contact opening 120 may be sufficiently smaller than that of the ridge structure. This is because the smaller width of the contact opening 120 does not cause changes in the ohmic contact resistance. It should be noted that the interface between the p-type cap layer 105 and the metal film pattern 106a is a substantial factor affecting the ohmic contact resistance.

Next, a top electrode layer 130 is formed over the whole surface of the resulting structure such that it is brought into contact with the metal film pattern 116a through the contact opening 120, to manufacture the final semiconductor laser device of the present embodiment.

Like in the previous embodiments, the semiconductor-metal interface for an ohmic contact opening is formed between the metal film pattern 116a and the p-type cap layer 105. Accordingly, the ohmic contact area at the ohmic contact face becomes large when compared to the prior art laser devices. Further, since dry etching for formation of the ridge structure is performed after the formation of the metal film pattern 116a and the protective insulating film pattern 108, no damage to the upper surface of the p-type cap layer 105 by dry etching occurs. Accordingly, the semiconductor surface that may affect the ohmic contact resistance is in direct contact with the upper metal film without being damaged. Moreover, since the contact opening 120 can be formed to have a small width, without an increase in ohmic contact resistance, a process margin in alignment can be improved.

As apparent from the foregoing, according to the present invention, since the ridge structure is formed using the metal film pattern or the protective insulating film pattern surrounding the metal film pattern, no damage to the surface of the semiconductor layer influencing the ohmic contact resistance occurs. In addition, the contact area between the semiconductor and the metal influencing the ohmic contact resistance can be greatly increased. Accordingly, the ohmic contact resistance can be reduced, and high-temperature, high-output characteristics of the semiconductor laser device are improved.

Furthermore, since the contact opening in contact with the metal film pattern has a small width, the process margin is improved, causing an increase in the yield of the semiconductor device. Therefore, high-quality devices can be manufactured on a commercial scale by the method of the present invention.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a semiconductor laser device, comprising the steps of:
sequentially laminating a first conductivity-type clad layer, an active layer, a second conductivity-type clad layer, and a second conductivity-type cap layer on a substrate;
forming a metal film pattern for formation of a ridge structure on the second conductivity-type cap layer;
etching the second conductivity-type cap layer and the second conductivity-type clad layer using the metal film pattern as an etching mask to form a ridge structure on the second conductivity-type clad layer;
forming a current blocking layer over a whole surface of the laminate on which the ridge structure is formed;
selectively etching the current blocking layer by photolithography to expose the metal film pattern and to form a contact opening; and
forming a top electrode layer on a surface of the metal film pattern exposed through the contact opening and on the current blocking layer.

2. The method according to claim 1, wherein the ridge structure is formed by wet etching.

3. The method according to claim 1, wherein the contact opening is formed to a width smaller than the width of the ridge.

4. The method according to claim 1, wherein the metal film pattern is formed by a lift-off process.

5. The method according to claim 1, wherein the metal film pattern is formed of a metal selected from Ti/Pt and Ti/Mo.

6. The method according to claim 1, wherein the current blocking layer is formed of an insulating layer.

7. A method for manufacturing a semiconductor laser device, comprising the steps of:
sequentially laminating a first conductivity-type clad layer, an active layer, a second conductivity-type clad layer, and a second conductivity-type cap layer on a substrate;
forming a metal film pattern on the second conductivity-type cap layer;
forming a protective insulating film pattern on the metal film pattern to protect the metal film pattern;
etching the second conductivity-type cap layer and the second conductivity-type clad layer using the protective insulating film pattern as an etching mask to form a ridge structure on the second conductivity-type clad layer;
forming a current blocking layer over a whole surface of the laminate on which the ridge structure is formed;
selectively etching the current blocking layer to expose the metal film pattern and to form a contact opening; and
forming a top electrode layer on a surface of the metal film pattern exposed by the contact opening and on the current blocking layer.

8. The method according to claim 7, wherein the step of forming a protective insulating film pattern includes the sub-steps of forming an insulating film on the metal film pattern, and selectively etching the insulating film to remove all portions except for a portion of the insulating film surrounding the metal film pattern.

9. The method according to claim 7, wherein the ridge structure is formed by dry etching.

10. The method according to claim 7, further comprising the step of removing the protective insulating film after the step of forming a ridge structure and prior to the step of forming a current blocking layer.

11. The method according to claim 7, wherein the contact opening is formed to a width smaller than the width of the ridge.

12. The method according to claim 7, wherein the metal film pattern is formed of a metal selected from Ti/Pt and Ti/Mo.

13. The method according to claim 7, wherein the protective insulating film pattern is formed of SiO₂, Si₃N₄, or SiON.

14. The method according to claim 7, wherein the current blocking layer is formed of an insulating layer.

15. A semiconductor laser device, comprising:
a first conductivity-type clad layer and an active layer sequentially laminated on a substrate;
a second conductivity-type clad layer formed on the active layer, the second conductivity-type clad layer having an upper region in a ridge structure;
a second conductivity-type cap layer formed on an upper surface of the ridge structure of the second conductivity-type clad layer;
a metal film pattern formed on the second conductivity-type cap layer;
a current blocking layer formed on a portion of an upper surface of the metal film pattern, both sides of the second conductivity-type cap layer, both sides of the ridge structure, and a bottom side of the second conductivity-type clad layer around the ridge structure, thereby exposing a portion of an upper surface of the metal film pattern; and
a top electrode layer formed on a portion of the exposed upper surface of the metal film pattern and on the current blocking layer.

16. The device according to claim 15, wherein the metal film pattern is formed to have a width substantially identical to the width of the ridge.

17. The device according to claim 15, wherein the metal film pattern is formed to a width smaller than the width of the ridge.

18. The device according to claim 15, wherein the semiconductor laser device is composed of an AlGaInP, AlGaAs, InGaAsP, AlInGaAs, or InGaN based semiconductor compound.

19. The device according to claim 15, wherein the metal film pattern is formed of a metal selected from Ti/Pt and Ti/Mo.

20. The device according to claim 15, wherein the current blocking layer is formed of an insulating layer.
